(19) United States
(12) Patent Application Publication
(10) Pub. No.: US 2014/0145766 A1
(43) Pub. Date: May 29, 2014

(54) INITIALIZATION CIRCUIT

(71) Applicant: SK HYNIX INC., Icheon-si (KR)

(72) Inventors: Myung Hwan LEE, Cheonan-si (KR); Yun Seok HONG, Icheon-si (KR)

(73) Assignee: SK HYNIX INC., Icheon-si (KR)

(21) Appl. No.: 13/845,196

(22) Filed: Mar. 18, 2013

(30) Foreign Application Priority Data
Nov. 29, 2012 (KR) 10-2012-0137368

(51) Int. Cl. H03L 5/00

(52) U.S. Cl. CPC H03L 5/00
USPC 327/143

(57) ABSTRACT

An initialization circuit includes an initialization control unit configured to generate a start pulse, which is generated after a power supply voltage reaches a target voltage level, in response to the power supply voltage and an external command, and an initialization execution unit configured to extract a fuse signal from a programmed fuse in response to the start pulse, and to output stored data when an external address corresponding to the fuse signal is inputted.

### CROSS-REFERENCES TO RELATED APPLICATIONS

The present application claims priority under 35 U.S.C. 119(a) to Korean Application No. 10-2012-0137368, filed on Nov. 29, 2012, in the Korean intellectual property Office, which is incorporated herein by reference in its entirety.

### BACKGROUND

In order to operate a semiconductor memory device, a power supply voltage VDD needs to be supplied from an external source. A voltage level of the power supply voltage VDD rises with a constant slope from 0 V to a target voltage level. When the power supply voltage VDD is directly applied to an internal circuit included in the semiconductor memory device, the internal circuit abnormally operates due to the rising power supply voltage. In order to substantially prevent the abnormal operation of the chip, the semiconductor memory device includes a power-up generation circuit to enable a power-up signal when the power supply voltage VDD reaches a stable voltage level.

When the power-up signal is enabled, the internal circuit included in the semiconductor memory device proceeds to perform various initialization operations. However, the voltage level of the power supply voltage VDD, at which the power-up signal is enabled, varies according to the rising speed of the power supply voltage VDD. For example, as illustrated in FIG. 1, when the power supply voltage VDD rises at a high speed, the power-up signal can be enabled at time t11 after the power supply voltage VDD reaches a target voltage level of 1.8 V, and an initialization operation can be performed between times t12 and t13. Since the initialization operation of the semiconductor memory device is performed after the power supply voltage VDD reaches the target voltage level, the semiconductor memory device may normally operate. However, as illustrated in FIG. 2, when the power supply voltage VDD rises at a low speed, the power-up signal can be enabled at time t14 after the power supply voltage VDD reaches 1.2 V, and an initialization operation can be performed between times t15 and t16. Since the initialization operation of the semiconductor memory device is performed before the power supply voltage VDD reaches the target voltage level of 1.8V, the semiconductor memory device may abnormally operate.

### SUMMARY

Various embodiments of the present invention relates to an initialization circuit that allows a semiconductor memory device to perform an initialization operation using an external command after a power supply voltage reaches a target voltage level regardless of the rising speed of the power supply voltage.

In an embodiment, an initialization circuit includes: an initialization control unit configured to generate a start pulse, which is generated after a power supply voltage reaches a target voltage level, in response to the power supply voltage and an external command; and an initialization execution unit configured to extract a fuse signal from a programmed fuse in response to the start pulse, and to output stored data when an external address corresponding to the fuse signal is inputted.

In another embodiment, an initialization circuit includes: a start pulse generation section configured to generate a start pulse, which is generated after a power supply voltage reaches a target voltage level, in response to a power-up signal and an external command; and a fuse section configured to extract a fuse signal from a programmed fuse when the start pulse is generated, and to output the fuse signal.

According to the present invention, it is possible to substantially prevent an initialization operation from being performed before a power supply voltage reaches a target voltage level, resulting in the prevention of an abnormal operation.

### BRIEF DESCRIPTION OF THE DRAWINGS

The above and other aspects, features and other advantages will be more clearly understood from the following detailed description taken in conjunction with the accompanying drawings, in which:

FIGS. 1 to 2 are diagrams for illustrating an initialization operation based on a power-up signal in the conventional art;

FIG. 3 is a block diagram illustrating the configuration of an initialization circuit according to an embodiment of the present invention;

FIG. 4 is a circuit diagram illustrating the fuse section included in the initialization circuit illustrated in FIG. 3 according to an embodiment of the present invention;

FIG. 5 is a block diagram illustrating the configuration of the data output section included in the initialization circuit illustrated in FIG. 3 according to an embodiment of the present invention; and

FIGS. 6 to 7 are diagrams for illustrating an initialization operation of the initialization circuit illustrated in FIG. 3 according to an embodiment of the present invention.

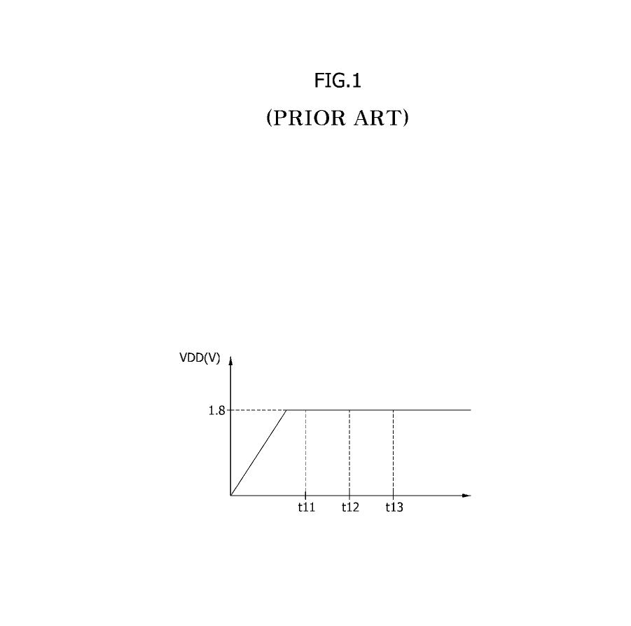

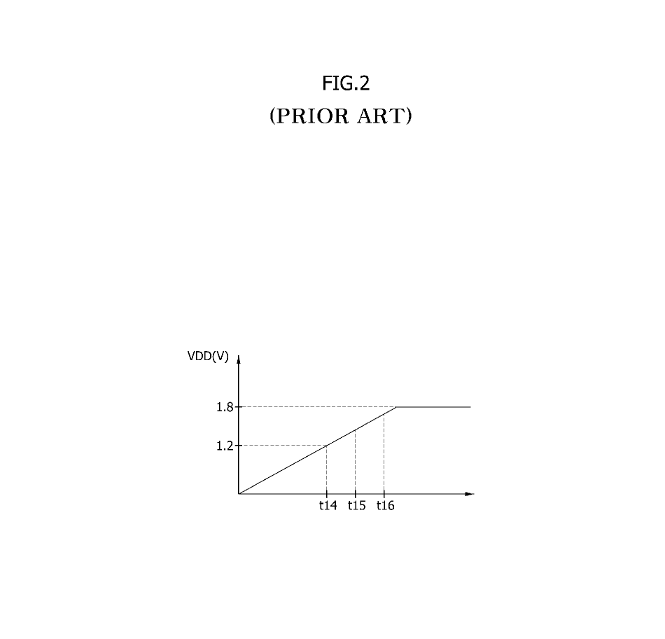

### DETAILED DESCRIPTION

Hereinafter, embodiments of the present invention will be described with reference to accompanying drawings. However, the embodiments are for illustrative purposes only and are not intended to limit the scope of the invention.

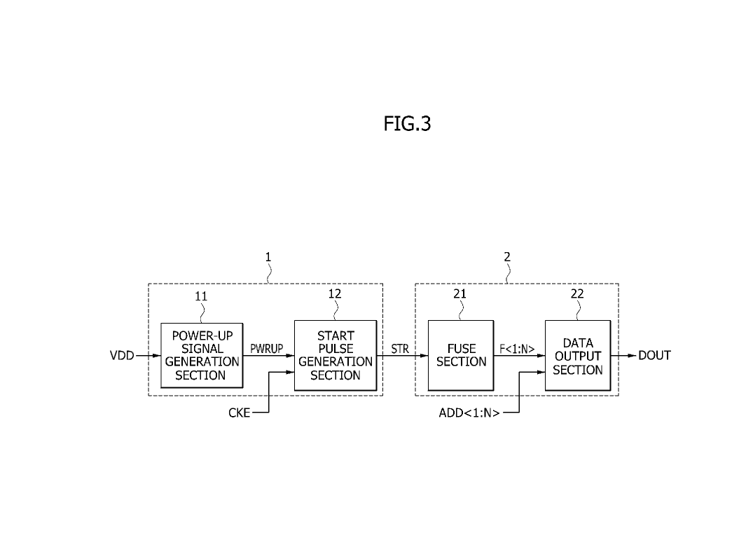

As illustrated in FIG. 3, the initialization circuit according to an embodiment of the present invention may include an initialization control unit 1 and an initialization execution unit 2. The initialization control unit 1 may be configured to generate a start pulse STR, which may be generated after a power supply voltage VDD reaches a target voltage level, in response to the power supply voltage VDD and a clock enable signal CKE. The initialization execution unit 2 may be configured to extract fuse signals F<1:N> from programmed fuses (not illustrated) in response to the start pulse STR, and to output stored data DOUT when external addresses ADD<1:N> corresponding to the fuse signals F<1:N> are inputted. The clock enable signal CKE may be an external command that is set to be enabled when the power supply voltage VDD has reached the target voltage level. According to another embodiment of the present invention, instead of the clock enable signal CKE, it may be possible to use another external command that is enabled when the power supply voltage VDD has reached the target voltage level.

The initialization control unit 1 may include a power-up signal generation section 11 and a start pulse generation section 12. The power-up signal generation section 11 may be configured to generate a power-up signal PWRUP in response to the power supply voltage VDD. A voltage level of the power-up signal PWRUP may rise proportionally with the power supply voltage VDD, and when the power supply voltage VDD reaches a predetermined level, the power-up signal PWRUP may be set to a logic low level, thereby enabling the power-up signal PWRUP. A voltage level of the power supply voltage VDD, at which time the power-up signal PWRUP is enabled, varies according to the rising speed of the power supply voltage VDD. For example, when the power supply voltage VDD rises at a low speed, the power-up signal PWRUP may be enabled at a corresponding lower voltage level of the power supply voltage VDD compared to when a power supply voltage VDD rises at a high speed. The start pulse generation section 12 may be configured to generate the start pulse STR when the clock enable signal CKE and the power-up signal PWRUP have been enabled and a predetermined time has passed. In an embodiment of the present invention, the start pulse STR may be activated as a signal having a logic low level corresponding to a predetermined pulse width. According to another embodiment, the start pulse STR may be activated as a signal having a logic high level.

The initialization execution unit 2 may include a fuse section 21 and a data output section 22. The fuse section 21 may be configured to initialize fuse signals F<1:N> before the start pulse STR is activated, and to output fuse signals F<1:N>, which have levels determined according to whether programmed fuses (not illustrated) have been cut, after the start pulse STR has been activated. The data output section 22 may be configured to output the internally stored data DOUT when the external addresses ADD<1:N> corresponding to the fuse signals F<1:N> have been inputted. The fuses included in the fuse section 21 may be programmed in order to store address information and the like of a failed cell. The fuse section 21 may include N fuses to generate N-bit fuse signals F<1:N>.

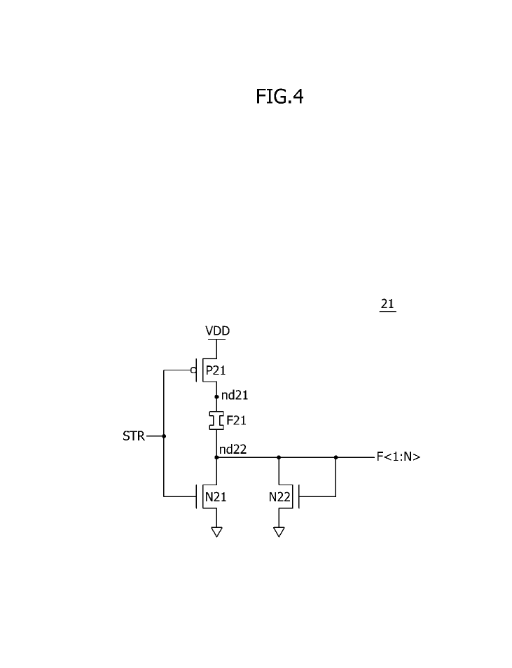

As illustrated in FIG. 4, the fuse section 21 may include a PMOS transistor P21, NMOS transistors N21 and N22, and a fuse F21. The fuse section 21 may initialize the fuse signals F<1:N> to a logic low level by a turned-on NMOS transistor N21 before the start pulse STR is activated (set to a logic high). When the start pulse STR is activated (set to a logic low), the PMOS transistor P21 may be turned on. Accordingly, when the start pulse STR is activated, the fuse section 21 may determine the level of the fuse signals F<1:N> according to whether the fuse F21 has been cut. For example, the fuse signals F<1:N> may substantially maintain a logic low level when the fuse F21 has been cut, and switch to a logic high level when the fuse F21 has not been cut. In the configuration of the fuse section 21 illustrated in FIG. 4, the fuse signals F<1:N> may be separately provided. That is, a plurality of electrical fuses (ARE, ARray E-fuse) may be included in the fuse section 21 to generate the fuse signals, which may include information regarding whether the included fuses have been cut.

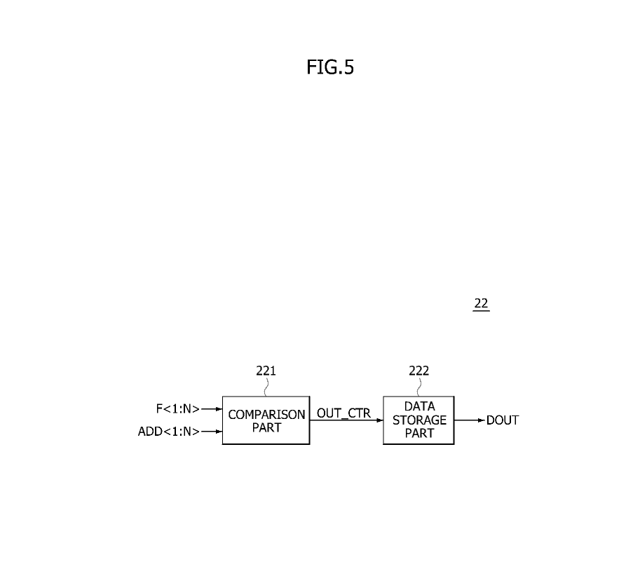

As illustrated in FIG. 5, the data output section 22 may include a comparison part 221 and a data storage part 222. The comparison part 221 may be configured to compare the fuse signals F<1:N> with the external addresses ADD<1:N>, and to output an output control signal OUT_CTR enabled when the fuse signals F<1:N> are substantially equal or similar to the external addresses ADD<1:N>. The data storage part 222 may be configured to internally store data DOUT, and to output the stored data DOUT when the enabled output control signal OUT_CTR is inputted.

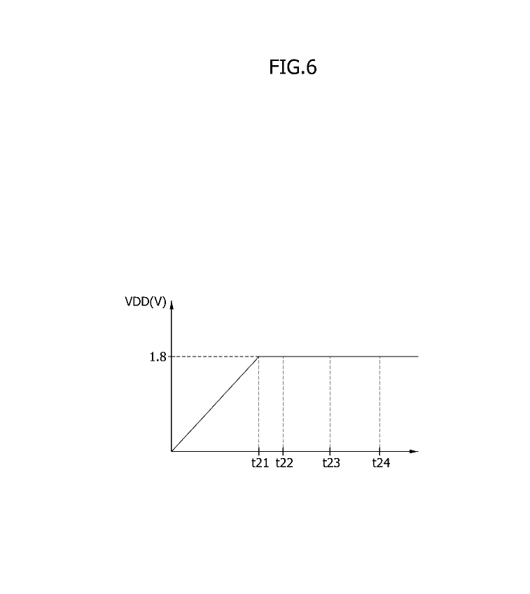

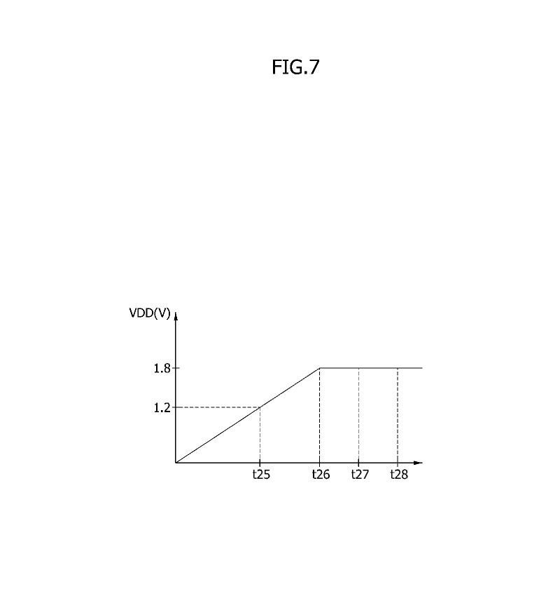

Hereinafter, a description will be provided for the initialization operation of the initialization circuit with reference to FIG. 6 when the power supply voltage VDD rises at a high speed, and with reference to FIG. 7 when the power supply voltage VDD rises at a low speed.

As illustrated in FIG. 6, when the power supply voltage VDD rises at a high speed, the clock enable signal CKE is enabled at time t21 at which the power supply voltage VDD has reached a target voltage level 1.8 V, and the power-up signal PWRUP is enabled at time t22. The start pulse STR may be generated at time point t23 after a predetermined time from time t22 at which the clock enable signal CKE and the power-up signal PWRUP have been enabled. Accordingly, the initialization circuit may perform the initialization operation for extracting the fuse signals F<1:N> during times t23 and t24, and output the data DOUT when the external addresses ADD<1:N> corresponding to the fuse signals F<1:N> are inputted.

As illustrated in FIG. 7, when the power supply voltage VDD rises at a low speed, the power-up signal PWRUP may be enabled at time t25 at which the power supply voltage VDD has reached a voltage level 1.2 V, short of the target voltage level 1.8 V. The clock enable signal CKE may be enabled at time t26 at which the power supply voltage VDD has reached the target voltage level 1.8 V. The start pulse STR may be generated at time t27 after a predetermined time from time t26 at which the clock enable signal CKE and the power-up signal PWRUP have been enabled. Accordingly, the initialization circuit may perform the initialization operation for extracting the fuse signals F<1:N> during times t27 and t28, and output the data DOUT when the external addresses ADD<1:N> corresponding to the fuse signals F<1:N> are inputted.

As described above, the initialization circuit according to various embodiments of the present invention substantially may prevent the occurrence of an abnormal operation in the initialization operation using the clock enable signal CKE that is enabled in synchronization with the time at which the power supply voltage VDD has reached the target voltage level 1.8 V. Even when the power-up signal PWRUP is enabled at a time the power supply voltage VDD has reached the voltage level 1.2 V, short of the target voltage level 1.8 V because the power supply voltage VDD rises at a low speed, the initialization circuit according to various embodiments of the present invention may perform the initialization operation using the clock enable signal CKE after the power supply voltage VDD reaches the target voltage level 1.8 V. Consequently, the initialization operation may be performed using the initialization circuit of the present invention, so that the initialization operation is substantially prevented from being performed before the power supply voltage VDD reaches the target voltage level 1.8 V.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. An initialization circuit comprising:
an initialization control unit configured to generate a start pulse, which is generated after a power supply voltage reaches a target voltage level, in response to the power supply voltage and an external command; and
an initialization execution unit configured to extract a fuse signal from a programmed fuse in response to the start pulse, and to output stored data when an external address corresponding to the fuse signal is inputted.

2. The initialization circuit of claim 1, wherein the external command is enabled in synchronization with a time when the power supply voltage has reached the target voltage level.

3. The initialization circuit of claim 2, wherein the external command includes a clock enable signal that is enabled for generation of an internal clock.

4. The initialization circuit of claim 2, wherein the initialization control unit comprises:
a power-up signal generation section configured to generate a power-up signal in response to the power supply voltage; and
a start pulse generation section configured to generate the start pulse in response to the power supply voltage and the external command.

5. The initialization circuit of claim 4, wherein the power-up signal is enabled when the power supply voltage reaches a predetermined level, after a voltage level of the power-up signal rises with the power supply voltage.

6. The initialization circuit of claim 5, wherein the start pulse is generated after a predetermined time interval when the power-up signal and the external command are enabled.

7. The initialization circuit of claim 2, wherein the initialization execution unit comprises:
a fuse section configured to extract the fuse signal from the programmed fuse when the start pulse is activated; and
a data output section configured to output the stored data when the external address corresponding to the fuse signal is inputted.

8. The initialization circuit of claim 7, wherein the fuse section is configured to initialize the fuse signal before the start pulse is activated, and to determine a voltage level of the fuse signal according to whether the fuse has been cut, when the start pulse is activated.

9. The initialization circuit of claim 7, wherein the data output section comprises:
a comparison part configured to output an output control signal enabled when the external address corresponds to the fuse signal; and
a data storage part configured to store the data, and to output the stored data when the output control signal is enabled.

10. An initialization circuit comprising:
a start pulse generation section configured to generate a start pulse, which is generated after a power supply voltage reaches a target voltage level, in response to a power-up signal and an external command; and
a fuse section configured to extract a fuse signal from a programmed fuse when the start pulse is activated, and to output the fuse signal.

11. The initialization circuit of claim 10, wherein the external command includes a clock enable signal that is enabled for generation of an internal clock.

12. The initialization circuit of claim 10, wherein the power-up signal is enabled when the power supply voltage reaches a predetermined level, after a voltage level of the power-up signal rises with the power supply voltage.

13. The initialization circuit of claim 12, wherein the external command is enabled in synchronization with a time when the power supply voltage has reached the target voltage level.

14. The initialization circuit of claim 13, wherein the start pulse is generated after a predetermined time interval when the power-up signal and the external command are enabled.

15. The initialization circuit of claim 10, wherein the fuse section is configured to initialize the fuse signal before the start pulse is activated, and to determine a voltage level of the fuse signal according to whether the fuse has been cut, when the start pulse is activated.

16. The initialization circuit of claim 10, further comprising:
a data output section configured to output stored data when the external address corresponding to the fuse signal is inputted.

17. The initialization circuit of claim 16, wherein the data output section comprises:
a comparison part configured to output an output control signal enabled when the external address corresponds to the fuse signal; and
a data storage part configured to store the data, and to output the stored data when the output control signal is enabled.
